(19) United States
(12) Patent Application Publication
(10) Pub. No.: US 2023/0232672 A1
(43) Pub. Date: Jul. 20, 2023

(54) DISPLAY SUBSTRATE, METHOD FOR MANUFACTURING THE SAME AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Kuo SUN, Beijing (CN); Yang WANG, Beijing (CN); Mingche HSIEH, Beijing (CN); Haijun YIN, Beijing (CN)

(73) Assignees: CHENGDU BOE OPTOELECTRONICS TECHNOLOGY CO., LTD., Chengdu (CN); BOE TECHNOLOGY GROUP CO., LTD., Beijing (CN)

(21) Appl. No.: 18/180,727

(22) Filed: Mar. 8, 2023

Related U.S. Application Data
(63) Continuation-in-part of application No. 16/346,435, filed on Apr. 30, 2019.

(30) Foreign Application Priority Data
Jan. 12, 2018 (CN) 201810031285.3

(51) Int. Cl. H01L 51/00; G01J 1/42; G06V 40/13; G01S 17/08; G06V 40/16

(52) U.S. Cl. CPC H10K 59/126; G01J 1/4204; G01S 17/08; G06V 40/16; G06V 40/1318; H10K 59/65; H10K 71/00; H10K 59/1201

(57) ABSTRACT

A display substrate, a method for manufacturing the same and a display device are provided. The display substrate includes a base substrate and a thin film transistor array arranged on the base substrate. Multiple pixels arranged in an array are provided in an effective display region of the display substrate. The effective display region includes an optical element arrangement region and other display regions, and a transmittance of the optical element arrangement region is larger than transmittances of the other display regions. In the optical element arrangement region, an optical element is arranged on a side of the base substrate away from the thin film transistor array, and the optical element emits and receives light that is transmitted through the display substrate.

### CROSS REFERENCE TO RELATED APPLICATIONS

This application is a continuation-in-part of U.S. Pat. Application No. 16/346,435, filed on Apr. 30, 2019, which is the U.S. National Phase of PCT Application No. PCT/CN2018/103145 filed on Aug. 30, 2018, which claims priority to Chinese Patent Application No. 201810031285.3 filed on Jan. 12, 2018, which are incorporated herein by reference in their entireties.

### TECHNICAL FIELD

The present disclosure relates to the field of display technology, in particular to a display substrate, a method for manufacturing the same and a display device.

### BACKGROUND

With the continuous improvement in industrial design and product assembling process, the utilization of internal space of a smart phone increases as the size of the smart phone increases. Nowadays, customers pursue not only large screens but also compact phone bodies while ensuring the sizes of the screens. Due to hardware homogenization, “screen-to-body ratio” has become a popular word in describing the appearance of a cellphone.

### SUMMARY

The present disclosure provides a display substrate, a method for manufacturing the same, and a display device.

In a first aspect, the present disclosure provides a display substrate. The display substrate includes an effective display region, the effective display region includes a first region and other display regions located on at least one side of the first region, a transmittance of the first region is greater than transmittances of the other display regions. The display substrate includes a base substrate. The display substrate includes a plurality of first pixels in the first region, located at a side of the base substrate, wherein at least one of the plurality of first pixels includes a first pixel circuit and a first light emitting element, the first pixel circuit is configured to drive the first light-emitting element to emit light, and the first pixel circuit includes a thin film transistor. The display substrate includes a light-shielding layer, located between the base substrate and the first pixel circuit, the light-shielding layer includes a shielding portion located in the first region, and an orthographic projection of the first pixel circuit onto the base substrate is located within an orthographic projection of the shielding portion onto the base substrate.

Optionally, the display substrate further includes a plurality of second pixels in the other display regions, located at the side of the base substrate, wherein at least one of the plurality of second pixels includes a second pixel circuit and a second light emitting element, the second pixel circuit is configured to drive the second light emitting element to emit light, and the second pixel circuit includes a thin film transistor.

The light-shielding layer further includes a first light-shielding pattern in the other display regions, and an orthographic projection of the second pixel circuit onto the base substrate is located within an orthographic projection of the first light-shielding pattern onto the base substrate.

Optionally, a size of the orthographic projection of the first pixel circuit in the first region onto the base substrate is smaller than a size of the orthographic projection of the second pixel circuit in the other display regions onto the base substrate.

Optionally, a distance between two adjacent first pixel circuits in the first region is greater than a distance between two adjacent second pixel circuits in the other display regions.

Optionally, a pixel density for the plurality of first pixels in the first region is lower than 200 pixels per inch.

Optionally, the display substrate further includes a plurality of imaging holes arranged in an array, the plurality of imaging holes are arranged in the shielding portion of the light-shielding layer, and the plurality of imaging holes is configured to enable the light to transmitted therethrough.

Optionally, the effective display region of the display substrate further includes a second region, a transmittance of the second region is greater than the transmittances of the other display regions. The display substrate further includes a plurality of third pixels in the second region, located at the side of the base substrate, at least one of the plurality of third pixels includes a third pixel circuit and a third light emitting element. The third pixel circuit is configured to drive the third light emitting element to emit light, and the third pixel circuit includes a thin film transistor.

The light-shielding layer further includes a second light-shielding pattern in the second region, and an orthographic projection of the third pixel circuit onto the base substrate is located within an orthographic projection of the second light-shielding pattern onto the base substrate.

Optionally, a size of the orthographic projection of the third pixel circuit in the second region onto the base substrate is smaller than a size of the orthographic projection of the second pixel circuit in the other display regions onto the base substrate.

Optionally, the shielding portion, the first shielding pattern and the second shielding pattern are located in the same layer and include the same material.

Optionally, the first light-shielding pattern, the second light-shielding pattern, and respective active layers have substantially the same size and shape, wherein the respective active layers are active layers of thin film transistors corresponding to the first light-shielding pattern and the second light-shielding pattern, respectively.

Optionally, the second region includes a first sub-region and a second sub-region. A light-shielding portion of the second light-shielding pattern, which is located in at least one of the first sub-region and the second sub-region, is capable of blocking infrared light, and the first sub-region and the second sub-region are arranged to be opposite to a face recognition circuit and a distance detection circuit, respectively.

Optionally, the second light-shielding pattern includes at least two light-shielding portions. In the second region, active layers of at least two thin film transistors are arranged on a light-shielding portion in the second light-shielding pattern, and an active layer of at least one thin film transistor adjacent to the at least two thin film transistors is arranged on another light-shielding portion in the second light-shielding pattern.

Optionally, the thin film transistor has a top-gate structure, and an orthographic projection of an active layer of the thin film transistor onto the base substrate falls within an orthographic projection of a gate electrode of the thin film transistor onto the base substrate.

In a second aspect, the present disclosure provides a display device, including the display substrate as described in the first aspect. The display device further includes a sensor, arranged on another side of the base substrate facing away from the plurality of first pixels.

Optionally, the display substrate further includes a plurality of second pixels in the other display regions, located at the side of the base substrate, wherein at least one of the plurality of second pixels includes a second pixel circuit and a second light emitting element. The second pixel circuit is configured to drive the second light emitting element to emit light, and the second pixel circuit includes a thin film transistor.

The light-shielding layer further includes a first light-shielding pattern in the other display regions, and an orthographic projection of the second pixel circuit onto the base substrate is located within an orthographic projection of the first light-shielding pattern onto the base substrate.

Optionally, a size of the orthographic projection of the first pixel circuit in the first region onto the base substrate is smaller than a size of the orthographic projection of the second pixel circuit in the other display regions onto the base substrate; or a distance between two adjacent first pixel circuits in the first region is greater than a distance between two adjacent second pixel circuits in the other display regions.

Optionally, the effective display region includes a second region, the second region is adj acent to a frame of the display device, and a transmittance of the second region is greater than the transmittance of the other display regions. The sensor includes a camera and an optical element. An orthographic projection of the camera onto the base substrate is at least partially located within the first region. An orthographic projection of the optical element onto the base substrate is at least partially located within the second region, and the optical element includes at least one of a face recognition circuit, a distance detection circuit, an environment light detection circuit, and a camera.

Optionally, the display device is configured to display an image with a low resolution in the second region, and the image includes at least one of an image for battery level, an image for signal strength, an image for time or an image for virtual button.

Optionally, the display device is a flexible display device, and the display device further includes a bottom film attached onto a non-display side of the display substrate, and a buffering shielding layer located on a side of the bottom film away from the display substrate. An opening is provided in the bottom film and the buffering shielding layer at a location corresponding to the optical element arrangement region, and the sensor is arranged on the base substrate through the opening.

In a third aspect, the present disclosure provides a method for manufacturing a display substrate as described in the first aspect, wherein the method includes: forming the base substrate; forming a light-shielding layer on the base substrate, including: forming a shielding portion located in the first region; forming a thin film transistor array on the light-shielding layer; and forming an anode, a light-emitting layer, and a cathode on the thin film transistor array; the thin film transistor array including a plurality of first pixels in the first region, at least one of the plurality of first pixels including a first pixel circuit and a first light emitting element, the first pixel circuit being configured to drive the first light-emitting element to emit light, the first pixel circuit including a thin film transistor, and an orthographic projection of the first pixel circuit onto the base substrate being located within an orthographic projection of the shielding portion onto the base substrate.

### BRIEF DESCRIPTION OF THE DRAWINGS

FIG. 1 schematic top view showing locations of a light-shielding pattern and an active layer of a thin film transistor according to some embodiments of the present disclosure;

FIG. 2 is a schematic top view of an imaging pattern according to some embodiments of the present disclosure;

FIG. 3 is a schematic top view of a display device according to some embodiments of the present disclosure;

FIGS. 4a and 4b are schematic cross-section views along line E1-E2 in FIG. 3 during a manufacturing process of a display device according to some embodiments of the present disclosure; and

FIGS. 5 and 6 are schematic cross-sectional views of the display device along the line E1-E2 in FIG. 3 according to some embodiments of the present disclosure;

FIGS. 7a to 7c are schematic partial enlarged cross-sectional views of the display device along the line E1-E2 in FIG. 3 according to some embodiments of the present disclosure;

FIGS. 8a-8b are schematic partial enlarged cross-sectional views of the display device along the line H1-H2 in FIG. 3 according to some embodiments of the present disclosure;

FIG. 8c is a schematic cross-sectional view of the display device along the line C1-C2 in FIG. 3 according to some embodiments of the present disclosure;

FIG. 9 is a flowchart of a method for manufacturing a display substrate according to some embodiments of the present disclosure;

FIG. 10 is a schematic top view of a display device according to some embodiments of the present disclosure;

FIG. 11 is a schematic cross-sectional view of the display device along the line F1-F2 in FIG. 10 according to some embodiments of the present disclosure;

FIG. 12a is a schematic top view of a display substrate after a light-shielding layer and a semiconductor layer are formed;

FIG. 12b is a schematic top view of the display substrate after a first gate metal layer is formed;

FIG. 12c is a schematic top view of the display substrate after the second gate metal layer is formed;

FIG. 12d is a schematic top view of the display substrate after the third insulating layer is formed;

FIG. 12e is a schematic top view of the display substrate after a source-drain metal layer is formed;

FIG. 13 is a schematic cross-sectional view of a display device according to some embodiments of the present disclosure;

FIG. 14 is a circuit diagram of a pixel circuit for at least one embodiment of the present disclosure; and

FIG. 15 is a timing diagram for the pixel circuit provided in FIG. 14.

### DETAILED DESCRIPTION

To better clarify technical problems to be solved, technical solutions and advantages according to some embodiments of the preset disclosure, detailed description is given based on drawings in conjunction with embodiments.

A narrow-bezel cellphone may improve a screen-to-body ratio and may be equipped with a large display screen within a small cellphone body, thereby leading to more perfect video and game experiences, and improving portability of the cellphone. Furthermore, the narrow-bezel cellphone has excellent visual effects, a fixed-size cellphone body may accommodate a larger screen, or a fixed-size screen may be accommodated in a more compact cellphone body.

Nowadays, a bezel of a cellphone product needs to provide some space for arranging structures such as a front-facing camera, a range sensor, an environment light sensor and a fingerprint recognition sensor. Consequently, the cellphone product cannot achieve real sense of full screen display.

In some embodiments, the present disclosure provides a display substrate, a method for manufacturing the same, and a display device, to increase a scree-to-body ratio of the display device and optimizing a display effect of the display device.

A display substrate is provided in some embodiments of the present disclosure. The display substrate may include a base substrate and a thin film transistor array arranged on the base substrate. Multiple pixels arranged in an array are provided in an effective display region of the display substrate. The effective display region includes an optical element arrangement region and other display regions. A transmittance of the optical element arrangement region is larger than transmittances of the other display regions. In the optical element arrangement region, an optical element is arranged on a side of the base substrate away from the thin film transistor array. The optical element emits light and such light transmits through the display substrate, and the optical element receives light that is transmitted through the display substrate.

In some embodiments of the present disclosure, the transmittance of the optical element arrangement region of the display substrate is larger than the transmittances of the other display regions; the optical element is arranged at a non-display side of the display substrate so there is no need to arrange the optical element at a bezel of the display device; and since the transmittance of the optical element arrangement region is relatively large, lights emitted from and received by the optical element may transmit through the display substrate. In view of the above, there is no need to reserve a space at the bezel of the display device to arrange the optical element, the screen-to-body ratio of the display device is enhanced, and the display effect of the display device is optimized.

FIG. 3 is a schematic top view of a display device according to some embodiments of the present disclosure. FIG. 5 is a schematic cross-sectional view of the display device taken along line E1-E2 of FIG. 3 according to some embodiments of the present disclosure. As exemplarily shown in FIGS. 3 and 5, embodiments of the present disclosure provide a display substrate 21. The display substrate 21 can form a display device together with an encapsulation cover plate 22. The display substrate 21 may include a base substrate 212 and a thin film transistor array 211 located on the base substrate. The effective display region 1 of the display substrate 21 is provided with a plurality of pixels arranged in an array. The effective display region 1 may include a region for arranging a sensor (which may be, for example, an optical element) or an optical element, and other display regions, wherein the region for arranging a sensor or an optical element includes a first region A and a second region B arranged along a first direction (denote as D1 in figures). Other display regions are located on at least one side of the first region (additionally, the second region). The second region B is adjacent to a frame of the display device, and both the first region A and the second region B are configured to display images. Although the first region A and the second region B are shown as rectangles in the figures, the first region A and the second region B may have a shape similar to that of the sensor (for example, a circle) according to actual needs.

As exemplarily shown in FIG. 5, the display substrate 21 further includes a light-shielding layer 23 located between the thin film transistor array 211 and the base substrate 212. The light-shielding layer 23 includes an imaging pattern (also called shielding portion herein) 31 corresponding to the first region A. The display device includes a sensor 15, arranged to be opposite to the first region. The sensor 15 may include a fingerprint recognition structure or a camera under the screen. In some embodiments, the light-shielding layer 23 includes a second light-shielding pattern 33 corresponding to the second region B. An optical element may be arranged to be opposite to the second region, under the screen (at the non-display side of the base substrate). The optical element is located at a side of the base substrate facing away from the thin film transistor array. The optical element is configured to emit and receive light through the display substrate. The optical element may include at least one of: a face recognition circuit 13, a distance detection circuit 11, an environment light detection circuit 12, or camera 14. In some embodiments, the face recognition circuit 13, the distance detection circuit 11, the environment light detection circuit 12, and the camera 14 are arranged in a second direction (denoted as D2 in figures), and are configured to emit and receive light in a third direction (denoted as D3 in figures) perpendicular to a display surface of the display region.

In some embodiments, in the light-shielding layer 23, regions other than shielding portion and light-shielding pattern are optically transparent regions. For example, optically transparent regions may be formed by etching materials away from the light-shielding layer. As another example, the optically transparent region may include a material with a transmittance higher than a predetermined threshold (for example, 90%).

In some embodiments, the light-shielding layer 23 is directly disposed on a surface of the display substrate 21 at a display side (namely, without any intervening structure).

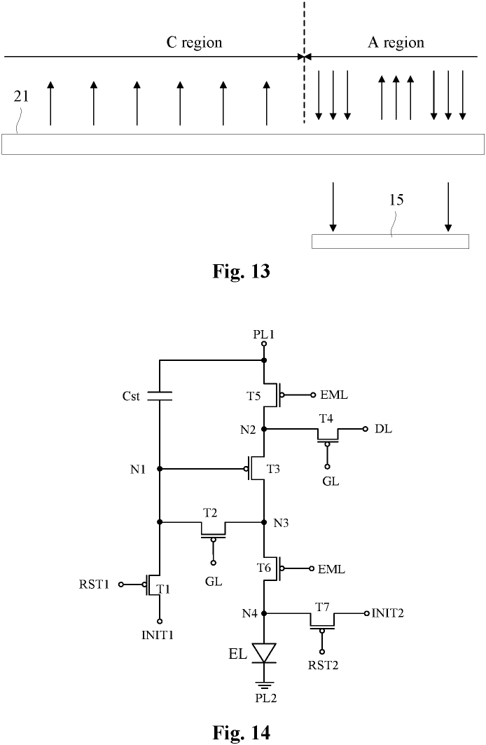

In some embodiments, the sensor or optical element is directly disposed on (e.g., attached to) a surface of the display substrate 21 at non-display side. In some other embodiments, as exemplarily shown in FIG. 13, the sensor (such as a fingerprint recognition structure or a camera) 15 or the optical element are arranged at the non-display side of the display substrate 21, and there is a distance from a surface of the display substrate 21 at the non-display side to the sensor 15 or the optical element.

It should be noted that although the thin film transistor array 211 is exemplarily shown as a single layer in FIG. 5, the thin film transistor may be a multi-layer structure as described below. In addition, there may be more layers (not shown) between the structures 211 and 22, such as a light emitting layer, a planarization layer, a pixel defining layer. For ease of description, in some drawings, only structures such as the pixel circuit or active layer, the light-shielding layer, and the base substrate are shown, and other conventional structures included in the display substrate are omitted.

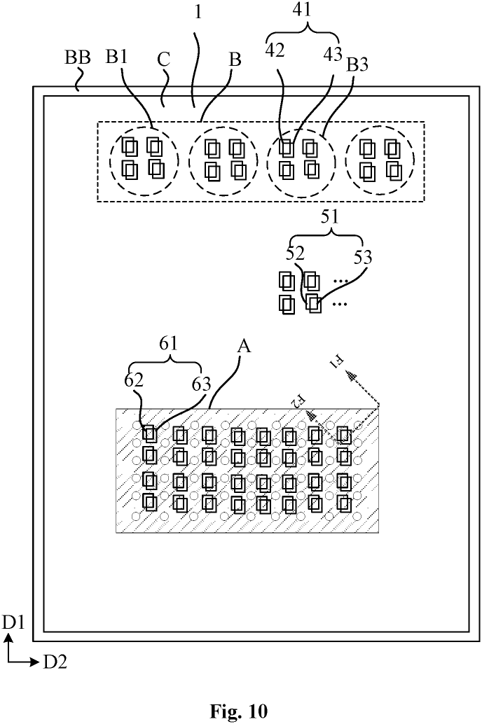

FIG. 10 is a schematic top view of a display device according to some embodiments of the present disclosure. FIG. 11 is a schematic cross-sectional view of the display device taken along the line F1-F2 in FIG. 10 according to some embodiments of the present disclosure. FIGS. 10 to 11 show an example implementation of the display device in FIG. 3. The display device includes a frame area BB and an effective display region 1 of a display substrate. The effective display region 1 includes a first region A and other display regions C located on at least one side of the first region, and a transmittance of the first region A is greater than transmittances of the other display regions C.

The display substrate includes a base substrate 212. The display substrate further includes a plurality of first pixels 61, located at a side of the base substrate 212 (for example, the display side) and located in the first region A. The first pixel 61 include a first pixel circuit 62 and a first light emitting element 63, the first pixel circuit 62 is configured to drive the first light emitting element 63 to emit light, and the first pixel circuit includes a thin film transistor.

The display substrate further includes a light-shielding layer 23 located between the base substrate 212 and the first pixel circuit 61. The light-shielding layer includes a shielding portion 31 located in the first region A. an orthographic projection of the first pixel circuit 62 onto the base substrate 212 is located within an orthographic projection of the shielding portion 31 onto the base substrate.

In some embodiments, the first region A may be an area for fingerprint recognition, and the fingerprint recognition structure (not shown in FIG. 11) may be disposed at the non-display side of the display substrate, opposite to the first region A. The display substrate may also include a plurality of imaging holes 32, which may be distributed in the shielding portion of the light-shielding layer in an array, and the imaging holes can transmit light for subsequent imaging (imaging for fingerprint recognition or imaging by under-screen camera). Since the shielding portion and the imaging holes are both located in the light-shielding layer, a single layer can be used for the fingerprint recognition based on pin-hole imaging (for example, through the imaging holes), as well as for protecting the pixel circuit (for example, active layers of various transistor in the pixel circuit) from being irradiated by light. In this way, two functions, including pixel circuit protection and imaging, can be realized with a simplified single-layer structure.

In some embodiments, the display substrate further includes a plurality of second pixels 51, located at the side of the base substrate (the display side) and in the other display regions C. The second pixel 51 includes a second pixel circuit 52 and a second light emitting element 53. The second pixel circuit is configured to drive the second light emitting element 53 to emit light, and the second pixel circuit includes a thin film transistor. The light-shielding layer 23 further includes a first light-shielding pattern 35 located in the other display regions, and an orthographic projection of the second pixel circuit 52 onto the base substrate is located within an orthographic projection of the first light-shielding pattern 35 onto the base substrate. The first light-shielding pattern can shield light (which may be emitted by the element arranged under the screen) from reaching the pixel circuit 52.

In some embodiments, the effective display region 1 of the display substrate further includes a second region B, a transmittance of the second region B is greater than the transmittances of the other display regions C. The display substrate further includes a plurality of third pixels 41, located at the side of the base substrate 212 (for example, the display side) and in the second region B. The third pixel includes a third pixel circuit 42 and a third light emitting element 43. The third pixel circuit 42 is configured to drive the third light emitting element 43 to emit light, and the third pixel circuit includes a thin film transistor. The light-shielding layer 23 further includes a second light-shielding pattern 33 located in the second region B, and an orthographic projection of the third pixel circuit 42 onto the base substrate is located within an orthographic projection of the second light-shielding pattern 33 onto the base substrate. Specific manners for arranging the second light-shielding pattern 33 is described in details in conjunction with FIGS. 3-8 hereinafter.

Although in FIG. 11, the pixel circuits 51 and 61 are shown as including a single thin film transistor 84, in some embodiments, the pixel circuits 41, 51 or 61 may each include a plurality of thin film transistors. Additionally, the pixel circuits 41, 51 or 61 may each include a capacitor. In some embodiments, orthographic projections of thin film transistors in the pixel circuits 41, 51 or 61 onto the base substrate, are located within an orthographic projection of the light-shielding layer 23 (for example, the imaging pattern 31, the first light-shielding pattern 35, the second light-shielding pattern 33) onto the base substrate. In some embodiments, an orthographic projection of the capacitor is also within the above orthographic projection of light-shielding layer.

As exemplarily shown in FIG. 11, in the third direction, each thin film transistor 84 may include an active layer (also referred to as a semiconductor layer) 34, a gate insulating layer 87, a gate metal layer G1, a second insulating layer 86, an interlayer insulating layer 85 and a source-drain metal layer S/D. At the top of the thin film transistor, the pixel circuit may further include structures such as a planarization layer 83, a pixel defining layer 82, an anode 81, a light emitting layer 88 and a cathode 89. The various light-emitting elements as described above may each include an anode, a light-emitting layer, and a cathode.

In some embodiments, the light-emitting element may be an organic light-emitting diode (OLED), and the light-emitting element may be configured to emit red light, green light, blue light, and additionally white light, under the driving of a corresponding pixel circuit. In some embodiments, some of the third pixels may only include sub-pixels capable of emitting light of a single color or two colors. For example, some of the third pixels, located in a sub-region of the second region B for displaying a battery level icon, may be configured to emit red light and/or green light only. Some of the third pixels, located in a sub-region of the second region for displaying icons such as signal strength, time, virtual button, may be configured to emit green light only. In this way, structures capable of blocking light in the pixel can be further reduced.

In some embodiments, the imaging pattern 31, the first light-shielding pattern 35 and the second light-shielding pattern 33 are located in the same layer (namely, light-shielding layer 23) and made of the same material. Therefore, the above three patterns can be formed simultaneously in a single patterning process (for example, by using the same mask).

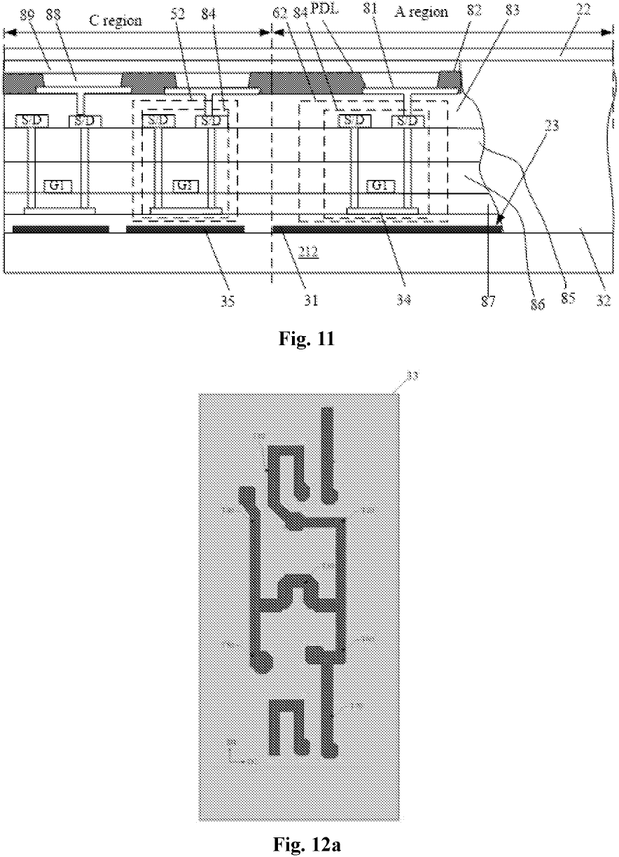

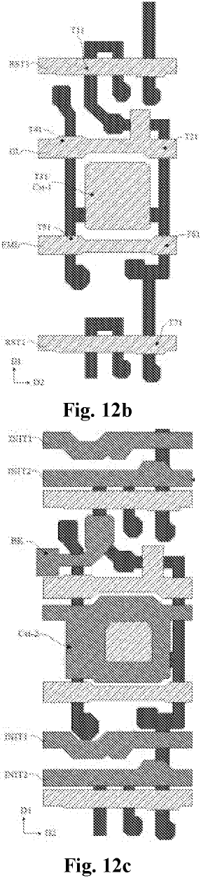

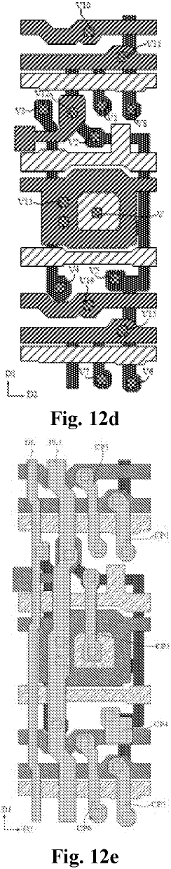

As exemplarily shown in FIG. 12a, in the light-shielding layer, various portions for light-shielding, each of which may correspond to a pixel circuit or a transistor, may be rectangular. In some embodiments, portions for light-shielding in the first light-shielding pattern 35 and the second light-shielding pattern 33 may have a substantially the same shape and size (equal to or slightly larger than the latter) as a semiconductor layer (which at least includes an active layer) of a thin film transistor in the corresponding pixel circuit. For example, portions for light-shielding in the first light-shielding pattern 35 and the second light-shielding pattern 33 may have substantially the same shape as the active layers of various transistors as shown in FIG. 12a. Therefore, the mask used for forming the semiconductor layer can be used again to form the first light-shielding pattern and the second light-shielding pattern, while a reduced shielding for light (a higher light transmittance) may be realized.

Since the face recognition circuit 13 and the distance detection circuit 11 generally emit infrared light towards the environment, in some embodiments, the second region B includes a first sub-region B3 and a second sub-region B1, and a light-shielding portion in the first light-shielding pattern 33 corresponding to at least one of the first sub-region B3 and the second sub-region B1 can block infrared light, and the first sub-region B3 and the second sub-region B1 correspond to the face recognition circuit 13 and the distance detection circuit 11, respectively. In this way, it is possible to effectively block infrared light from damaging the pixel circuit (such as the active layer included in the pixel circuit). It will be understood that when the imaging pattern 31, the first light-shielding pattern 33 and the first light-shielding pattern 35 are made of the same material, such material is a material capable of blocking infrared light.

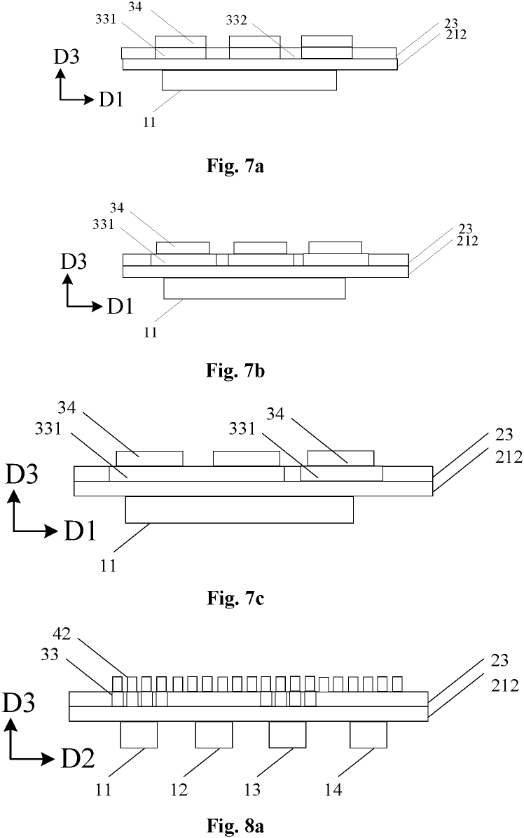

In some embodiments, as shown in FIG. 7c, in the second region B, active layers 34 of at least two thin film transistors are disposed on a light-shielding portion 331 in the first light-shielding pattern, and an active layer 34 of at least one thin film transistor adjacent to the two thin film transistors is disposed on another light-shielding portion 331 in the first light-shielding pattern. The arrangement as shown in FIG. 7c can also be applied to the first region and the other display regions in a similar manner, and the description thereof is omitted herein.

In the display substrate according to embodiments of the present disclosure, structures which may block light transmission mainly includes various pixel circuits, including the thin film transistor(s) in the pixel circuit (for example, the gate metal therein), and the light-shielding layer. In some embodiments, a size of the orthographic projection of the pixel circuit (for example, the first pixel circuit or the third pixel circuit) in the first region A or the second region B onto the base substrate 212, is smaller than a size of the orthographic projection of the pixel circuit (for example, the second pixel circuit) in the other display regions C onto the base substrate 212. In some embodiments, a size of an orthographic projection of thin film transistor(s) in the first region A or the second region B (for example, thin film transistor(s) in the first pixel circuit or the third pixel circuit) onto the base substrate 212, is smaller than a size of an orthographic projection of thin film transistor(s) (for example, thin film transistor(s) in the second pixel circuit) in the other display regions C onto the base substrate 212. In some embodiments, a size of an orthographic projection for an active layer of the thin film transistor in the first region A or the second region B (for example, an active layer of the thin film transistor in the first pixel circuit or the third pixel circuit) onto the base substrate 212, is smaller than a size of an orthographic projection for an active layer of the thin film transistor in the other display regions C (for example, an active layer of the thin film transistor in in the second pixel circuit) onto the base substrate 212. It should be noted that the size of the above mentioned orthographic projections may refer to an area occupied by the above mentioned orthographic projections on the base substrate 212. In this way, the area occupied by the pixel circuit (and additionally, corresponding portions for light-shielding in the light-shielding layer) in the regions A and B where the optical element and sensor are arranged, can be smaller than the area occupied by the pixel circuit in other display regions C, thereby improving the transmittance for the regions A and B.

In some embodiments, a distance between two adjacent pixel circuits in the first region A or the second region B (for example, adjacent first pixel circuits, or adjacent third pixel circuits), is greater than a distance between two adjacent pixel circuits (for example, adjacent second pixel circuits) in the other display regions C.

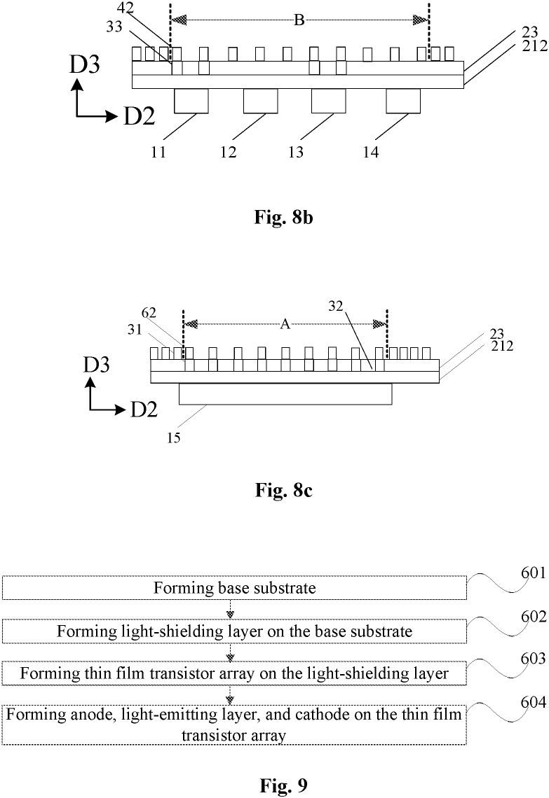

As shown in FIGS. 8b and 8c, in some embodiments, the distance between two adjacent pixel circuits in the first region A or the second region B is greater than the distance between two adjacent pixel circuits in the other display regions C. In this way, on the same area, the number of pixel circuits (and corresponding portions for light-shielding) in these regions A or B can be less than the number of pixel circuits in other display regions. As a result, the total area occupied by the pixel circuits in these regions A or B (and corresponding portions for light-shielding) will be smaller than the total area occupied by the pixel circuits in other display regions, thereby increasing the transmittance for the regions A and B.

FIGS. 7a to 7c are schematic cross-sectional enlarged views for a portion of the display substrate taken along the line E1-E2 in FIG. 3 according to some embodiments of the present disclosure, which show a cross-sectional structure corresponding to the second region. Although the present application takes the second region as an example for illustration, it can be understood that a similar arrangement can also be applied to the first region and other display regions.

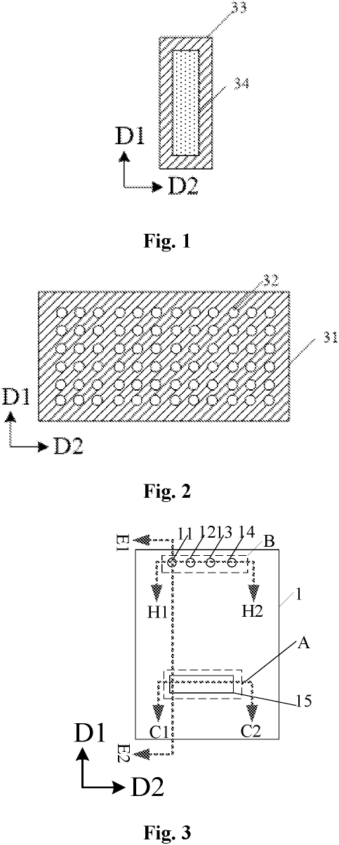

As exemplarily shown in FIGS. 7a to 7c, the light-shielding pattern 33 includes a light-shielding portion 331 and an optically transparent portion 332. As shown exemplarily in FIG. 1, the active layer 34 of the thin film transistor in the second region B is arranged on one light-shielding portion 331, and an orthographic projection of the active layer 34 of the thin film transistor in the second region onto the base substrate 212 is located within an orthographic projection of the light-shielding portion 331 onto the base substrate 212.

For example, in a case that the thin film transistor is a low-temperature polysilicon thin film transistor, and the active layer 34 of the thin film transistor is made of a low-temperature polysilicon, the light-shielding layer 23 may shield light emitted by a light source in the optical element 11, such that the light is prevented from striking onto the active layer 34 made of the low-temperature polysilicon, and the performance of the low-temperature polysilicon thin film transistor may not be affected. The light-shielding layer may be made of a metal such as Mo, or may be made of other light-shielding materials, which is not limited herein.

As exemplarily shown in FIG. 7a, in some embodiments, an area of each active layer 34 is equal to an area of the light-shielding portion 331 corresponding to each active layer 34 in the light-shielding pattern 33. As exemplarily shown in FIG. 7b, in some embodiments, the area of each active layer 34 is smaller than the area of the light-shielding portion 331 corresponding to each active layer 34 in the light-shielding pattern 33. As a result, the light can be prevented from reaching the optical element or sensor and the light will not irradiate the active layer.

As exemplarily shown in FIG. 7c, in some embodiments, the light-shielding pattern 33 includes at least two light-shielding portions 331, and in the second region, active layer 34 of at least two thin film transistors (for example, two thin film transistors at the left side in FIG. 7c) is disposed on one light shielding portion in the second light-shielding pattern, and at least one thin film transistor (for example, the one thin film transistor at the right side in FIG. 7c) adjacent to the at least two thin film transistors is disposed on another light-shielding portion in the second light-shielding pattern. In other words, the light-shielding portions in the light-shielding pattern 33 may not be arranged in one-to-one correspondence with the thin film transistors, as long as there is a channel (for example, an optically transparent portion) for light transmission, and the amount of emitted/received light can ensure the normal function of the optical element or sensor.

FIGS. 8a and 8b are schematic cross-sectional enlarged views of a portion of the display substrate taken along the line H1-H2 in FIG. 3 according to some embodiments of the present disclosure, which show a cross-sectional structure corresponding to the second region. As exemplarily shown in FIGS. 8a to 8b, in some embodiments, the distance detection circuit 11 and the face recognition circuit 13 are configured to emit and receive infrared light through the display substrate 212. Therefore, the pixel circuits in the corresponding region may be irradiated by light which is emitted from an infrared light source under the base substrate in the third direction towards the encapsulation cover plate 22. The environment light detection circuit 12 and the camera 14 are configured to receive light without emitting light through the display substrate 212. Therefore, the pixel circuits in the corresponding region are less likely to be irradiated by light from the light source under the screen.

Therefore, the pixel circuits 42 located in the first sub-region and the second sub-region in the second region, which are corresponding to at least one of the face recognition circuit 13 or the distance detection circuit 11, are arranged on the light-shielding portion, while the pixel circuits 42 located in other sub-regions in the second region, which are corresponding to at least one of the environment light detection circuit 12 or the camera 14, are arranged on the optically transparent portion. In this way, the light-shielding portion and the optically transparent portion in the light-shielding pattern can be arranged accordingly depending on different characteristics of various optical elements, so as to avoid unintended light shielding which may disadvantageously affect the performance of the optical element.

FIG. 8c is a schematic cross-sectional view of the display substrate taken along line C1-C2 according to some embodiments of the present disclosure, which shows a cross-sectional structure corresponding to the first region. As shown exemplarily in FIGS. 8c, 2 and 3, in some embodiments of the present disclosure, an optical element arrangement region may include a first region A. The imaging pattern 31 corresponds to the first region and is provided with multiple imaging holes 32 arranged in an array. The optical element may include a fingerprint recognition structure 15. The fingerprint recognition structure 15 may be arranged corresponding to the first region A, for example, the fingerprint recognition structure is arranged directly facing the first region A. A light source in the fingerprint recognition structure emits light out of the display substrate, and the light is reflected after arriving at a finger of a user. A photoelectric converter is arranged in the fingerprint recognition structure. Via the first region having a relatively high transmittance, the reflected light is received by the photoelectric converter based on a pin-hole imaging principle, and a fingerprint of the user may be imaged on the photoelectric converter through the imaging holes, thereby accomplishing fingerprint acquisition at corresponding imaging holes. The photoelectric converter may utilize photosensitive components such as Complementary Metal Oxide Semiconductor (CMOS) or Charge-coupled Device (CCD), to acquire the fingerprint.

As exemplarily shown in FIG. 8c, in some embodiments, in the first region A, an orthographic projection of the pixel circuit 62 onto the base substrate 212 falls within an orthographic projection of the imaging pattern 31 onto the base substrate 212, so that the pixel circuit (including the active layer thereof) will not be irradiated by light emitted from the bottom of the screen in the third direction. In some embodiments, the imaging hole corresponds to a gap (channel) between adjacent pixel circuits, so that light cannot be blocked by structures such as thin film transistors before reaching the finger or the imaging sensor. In some embodiments, the imaging hole may also correspond to a gap between adjacent groups of pixel circuits (for example, three pixel circuits per group).

In some embodiments of the present disclosure, the optical element arrangement region may further include a second region. The light-shielding pattern corresponds to the second region and the other display regions. The optical element includes at least one of a face recognition circuit, a distance detection circuit and an environment light detection circuit. The at least one of the face recognition circuit, the distance detection circuit and the environment light detection circuit is arranged corresponding to the second region. The at least one of the face recognition circuit, the distance detection circuit and the environment light detection circuit may emit light or receive light that is transmitted through the second region of the display substrate, to perform an optical detection.

The transmittance of the optical element arrangement region may be enhanced with many approaches. For example, a pixel density of the optical element arrangement region may be set to be smaller than pixel densities of the other display regions. With the optical element arrangement region having a low pixel density, a light-shielding effect of pixels may be alleviated, such that the optical element may receive sufficient external light that is transmitted through the display substrate corresponding to the optical element arrangement region.

The pixel densities of the other display regions of the display substrate are usually higher than 500 PPI. In an optional embodiment, the pixel density of the optical element arrangement region (which, for example, includes the above mentioned first and second regions A and B) is lower than 200 PPI (Pixels Per Inch), such that the transmittance of the optical element arrangement region is high enough, and the optical element can receive sufficient external light that is transmitted through the display substrate corresponding to the optical element arrangement region. In addition, since the optical element arrangement region is stilled provided with pixels, the optical element arrangement region can still display, and image integrity is not affected. For example, the optical element arrangement region may display images of not high display requirements, such as images of battery level, signal strength, time and virtual buttons.

In some other embodiments of the present disclosure, the optical element arrangement region may be constructed into a region having no pixels. The optical element arrangement region maintains in a transparent state and no image is displayed there, such that the optical element can receive sufficient external light via the display substrate corresponding to the optical element arrangement region.

Furthermore, sizes of pixels corresponding to the optical element arrangement region may be set to be smaller than sizes of pixels in the other display regions. Hence, the light-shielding effect of the pixels can be further alleviated, and the optical element can receive sufficient external light via the display substrate corresponding to the optical element arrangement region.

Furthermore, the optical element arrangement region may be arranged at a certain corner of the effective display region, for example, an upper right corner, an upper left corner or a lower right corner, to best alleviate an effect on a displayed image.

Optionally, the thin film transistor may have a top-gate structure, an orthographic projection of an active layer of the thin film transistor onto the base substrate falls within an orthographic projection of a gate electrode of the thin film transistor onto the base substrate, such that the gate electrode of the thin film transistor can shield the external light, external light is prevented from striking onto the active layer of the thin film transistor and accordingly, the performance of the thin film transistor is not affected.

According to some embodiments of the present disclosure, a method for manufacturing the display substrate provided by the embodiments of the disclosure is further provided. As shown in FIG. 9, the method includes forming the base substrate (step 601). The method further includes forming a light-shielding layer on the base substrate (step 602), including: forming a shielding portion located in the first region. The method further includes forming a thin film transistor array on the light-shielding layer (step 603); the thin film transistor array including a plurality of first pixels in the first region, at least one of the plurality of first pixels including a first pixel circuit and a first light emitting element, the first pixel circuit being configured to drive the first light-emitting element to emit light, the first pixel circuit including a thin film transistor, and an orthographic projection of the first pixel circuit onto the base substrate being located within an orthographic projection of the shielding portion onto the base substrate. The method further includes forming an anode, a light-emitting layer, and a cathode on the thin film transistor array (step 604).

In some embodiments, the step of forming the light-shielding layer on the base substrate may include: forming the shielding portion, the first light-shielding pattern in the other display regions, and the second light-shielding pattern in the second region through one single patterning process.

In some embodiments of the present disclosure, the method for manufacturing the display substrate may include following steps 1 to 9.

Step 1 includes: providing a base substrate 212 and forming a light-shielding layer 23 on the base substrate 212.

The base substrate 212 may be a glass substrate or a quartz substrate. For example, an initial light-shielding layer having a thickness of about 300 to 1500Å is deposited on the base substrate 212 in a sputtering or thermal evaporation manner. The initial light-shielding layer may be made of Mo. A layer of photoresist is coated on the initial light-shielding layer and is exposed using a mask to generate a photoresist unreserved region and a photoresist reserved region. The photoresist reserved region corresponds to regions where the first and second light-shielding patterns and the shielding portion of the light-shielding layer are located. The photoresist unreserved region corresponds to a region except for the region where the light-shielding pattern or portion of the light-shielding layer is located (for example, regions corresponding to the imaging holes, optically transparent portions included in various shielding patterns). A developing process is performed, the photoresist in the photoresist unreserved region is completely removed, and a thickness of the photoresist in the photoresist reserved region is maintained unchanged. The light-shielding layer in the photoresist unreserved region is completely etched via an etching process, and the remained photoresist is peeled off to form the pattern of the light-shielding layer 23. The pattern of the light-shielding layer 23 includes light-shielding patterns 33 and 35, and an imaging pattern 31.

Optionally, the pattern of the light-shielding layer 23 may be formed through a patterning process (e.g., photolithography). Optionally, the pattern of the light-shielding layer 23 is formed by two patterning processes, wherein the second light-shielding pattern 33 and the first light-shielding pattern 35 are formed by one patterning process. The fabrication of the second light-shielding pattern 33 and the first light-shielding pattern 35 can reuse the pattern of the active layer of the corresponding thin film transistor(s) in regions B and C.

FIG. 1 schematically shows locations of the light-shielding pattern and the active layer of the thin film transistor according to some embodiments of the present disclosure. As shown in FIG. 1, the light-shielding pattern 33 is arranged corresponding to the active layer 34 of the thin film transistor. An orthographic projection of the active layer 34 of the thin film transistor onto the base substrate falls within an orthographic projection of the first light-shielding pattern 33 onto the base substrate. The imaging pattern is arranged corresponding to a fingerprint recognition structure. As shown in FIG. 2, the imaging pattern 31 is provided with multiple imaging holes 32 arranged in an array. As shown in FIG. 10, in regions C and A, an orthographic projection of the pixel circuit (for example, a thin film transistor or its active layer included therein) onto the base substrate falls within an orthographic projection of the first light-shielding pattern 35 and/or the imaging pattern 31 onto the base substrate.

Step 2 includes: forming an insulating layer and a pattern of the active layer of each thin film transistor on the base substrate after step 1.

For example, an insulating layer material and a low-temperature polysilicon material are successively deposited on the base substrate after step 1. The low-temperature polysilicon material is patterned by a patterning process. For example, layer of photoresist is coated on the low-temperature polysilicon material. The photoresist is exposed using a mask to generate a photoresist unreserved region and a photoresist reserved region. The photoresist reserved region corresponds to a region where a pattern of the active layer is located. The photoresist unreserved region corresponds to a region in addition to the region where the pattern of the active layer is located. A developing process is performed, the photoresist in the photoresist unreserved region is completely removed, and a thickness of the photoresist in the photoresist reserved region is maintained unchanged. The low-temperature polysilicon material in the photoresist unreserved region is completely etched via an etching process, and remained photoresist is peeled off to form the pattern of the active layer. As shown in FIGS. 1 and 10, the orthographic projection of the pixel circuit (which for example, includes thin film transistor and the active layer of the thin film transistor) onto the base substrate falls within the orthographic projection of the light-shielding layer 23 (which for example, includes the first light-shielding pattern, the second light-shielding pattern and the imaging pattern) onto the base substrate.

In some exemplary embodiments, FIG. 12a is a schematic top view of the display substrate after the light-shielding layer and the semiconductor layer (which may, for example, include the above-mentioned active layer) on the light-shielding layer is formed in the step 2. The semiconductor layer may include: active layers of a plurality of transistors in one pixel circuit (which may be the first pixel circuit, the second pixel circuit or the third pixel circuit as described above) For example, the active layers includes: an active layer T10 of a first reset transistor T1, an active layer T20 of a threshold compensation transistor T2, an active layer T30 of a driving transistor T3, an active layer T40 of a data writing transistor T4, and an active layer T50 of a first light emitting control transistor T5, an active layer T60 of a second light emitting control transistor T6, and an active layer T70 of a second reset transistor T7. The active layers of the seven transistors in the pixel circuit may be connected to each other as a one-piece structure.

Step 3 includes: forming a pattern of a gate insulating layer 87 on the base substrate after step 2.

For example, a gate insulating layer having a thickness ranging from 500Å to 5000Å is deposited on the base substrate after step 2 with a manner of plasma enhanced chemical vapor deposition (PECVD). The gate insulating layer may be made of an oxide, a nitride or a nitric oxide, and a corresponding reactant gas may be SiH4, NH3, N2 or SiH2C12, NH3, N2. The pattern of the gate insulating layer 87 includes a via-hole, and the pattern such as the first light-shielding pattern 33 is electrically connected to a preset electric potential point through the via-hole penetrating through the gate insulating layer.

Step 4 includes: forming a pattern of a gate metallic layer G1 on the base substrate after step 3.

For example, a gate metallic layer having a thickness of about 500 to 4000Å is deposited on the base substrate after step 3 with a manner of sputtering or thermal evaporation. The gate metallic layer may be made of Cu, Al, Ag, Mo, Cr, Nd, Ni, Mn, Ti, Ta or W, or any alloy of the above metals. The gate metallic layer may have a single layer structure or a multilayer structure such as Cu\Mo, Ti\Cu\Ti, Mo\Al\Mo. The gate metallic layer is then patterned by a patterning process. For example, a layer of photoresist is coated on the gate metallic layer, and is exposed using a mask to generate a photoresist unreserved region and a photoresist reserved region. The photoresist reserved region corresponds to a region where a pattern of the gate metallic layer is located. The pattern of the gate metallic layer includes a gate line and a gate electrode. The photoresist unreserved region corresponds to a region in addition to the region where the pattern of the gate metallic layer is located. A developing process is performed, the photoresist in the photoresist unreserved region is completely removed and a thickness of the photoresist in the photoresist reserved region is maintained unchanged. A gate metallic film in the photoresist unreserved region is completely etched via an etching process and remained photoresist is peeled off to form the pattern of the gate metallic layer.

In some exemplary embodiments, step 4 may specifically include step 4-1 and step 4-2.

Step 4-1 includes: depositing a first metal thin film layer on the base substrate on which the step 3 is done, and patterning the first metal thin film layer through a patterning process to form a pattern of a first gate metallic layer on the insulating layer 87.

In some exemplary embodiments, FIG. 12b is a schematic top view of the display substrate on which the first gate metal layer is formed by the step 4-1 (For a better illustration, the light-shielding layer is not shown in this figure and subsequent FIGS. 12c-12e). As shown in FIG. 12b, the first gate metallic layer may include: gate electrodes of multiple transistors in the pixel circuit, a first capacitor plate Cst-1 of a storage capacitor Cst, a first reset control line RST1, a second reset control line RST2, a scanning line GL and a light emitting control line EML. The first reset control line RST1 and a gate electrode T11 of the first reset transistor T1 may be one-piece structure. The scanning line GL, a gate electrode T41 of the data writing transistor T4 and a gate electrode T21 of the threshold compensation transistor T2 may be one-piece structure. A gate electrode T31 of the driving transistor T3 and the first capacitor plate Cst-1 of the storage capacitor Cst may have one-piece structure. The light emitting control line EML, a gate electrode T51 of the first light emitting control transistor T5 and a gate electrode T61 of the second light emitting control transistor T61 may be one-piece structure. The second reset control line RST2 and a gate electrode T71 of the second reset transistor T7 may be one-piece structure.

Step 4-2 includes: depositing a second insulating film and a second metal thin film layer sequentially on the base substrate on which the step 4-1 is done, and patterning the second metal thin film layer through a patterning process to form a second insulating layer covering the first gate metallic layer, and a second gate metallic layer on the second insulating layer.

In some exemplary embodiments, FIG. 12c is a schematic top view of the display substrate after the second gate metallic layer is formed by step 4-2. As shown in FIG. 12c, the second gate metallic layer may include: a second capacitor plate Cst-2 of the storage capacitor Cst in the pixel circuit, a shielding electrode BK, a first initial signal line INIT1 and a second initial signal line INIT2. The shielding electrode BK may be configured to shield the influence of the data voltage jump on key nodes, avoiding the data voltage jump from affecting voltage potentials at the key nodes of the pixel circuit, and thereby improving the display effect.

Step 5 includes: forming a pattern for an intermediate insulating layer (also call a third insulating layer) 85 on the base substrate after step 4.

For example, the intermediate insulating layer having a thickness of 500 to 5000 Å is deposited on the base substrate after step 4 in a PECVD manner. The intermediate insulating layer may be made of an oxide, a nitride or a nitric oxide, and a corresponding reactant gas may be SiH4, NH3, N2 or SiH2C12, NH3, N2. Through a patterning process, a plurality of pixel via holes is formed in the third insulating layer 85.

In some exemplary embodiments, FIG. 12d is a schematic top view of the display substrate after the third insulating layer is formed by step 5. The third insulating layer 85 may be provided with a plurality of pixel via holes, which for example, may include a first pixel via hole V1 to a fifteenth pixel via hole V15. The third insulating layer 85, the second insulating layer and the gate insulating layer 87 in the first pixel via hole V1 to the eighth pixel via hole V8 are removed to expose a surface of the active layer. The third insulating layer 85 and the second insulating layer in the ninth pixel via hole V9 are removed to expose a surface of the first gate metallic layer. The third insulating layer 85 in the tenth pixel via hole V10 to the fifteenth pixel via hole V15 is removed to expose a surface of the second gate metallic layer.

Step 6 includes: forming a pattern of a source and drain metallic layer on the base substrate after step 5.

For example, a source and drain metallic layer having a thickness of about 2000 to 4000Å is deposited on the base substrate after step 5 in a sputtering or thermal evaporation manner, or in other film forming manners. The source and drain metallic layer may be made of Cu, Al, Ag, Mo, Cr, Nd, Ni, Mn, Ti, Ta or W, or any alloy of the above metals. The source and drain metallic layer may have a single layer structure or a multilayer structure such as Cu\Mo, Ti\Cu\Ti, Mo\Al\Mo. The source-drain metal layer is patterned through a patterning process. For example, a layer of photoresist is coated on the source and drain metallic layer and is exposed using a mask to generate a photoresist unreserved region and a photoresist reserved region. The photoresist reserved region corresponds to a region where a pattern of the source and drain metallic layer is located. The photoresist unreserved region corresponds to a region in addition to the region where the pattern of the source and drain metallic layer is located. A developing process is performed, the photoresist in the photoresist unreserved region is completely removed and a thickness of the photoresist in the photoresist reserved region is maintained unchanged. The source and drain metallic layer in the photoresist unreserved region is completely etched via an etching process and remained photoresist is peeled off to form the pattern of the source and drain metallic layer. The pattern of the source and drain metallic layer may include a source electrode, a drain electrode and a data line. The source electrode and the drain electrode may be connected to the active layer through via-holes penetrating through the intermediate insulating layer and the gate insulating layer.

In some exemplary embodiments, FIG. 12e is a schematic top view of the display substrate after the source-drain metal layer is formed by step 6. The source-drain metal layer may include: a data line DL, a first power line PL1, and a plurality of connection electrodes (for example, a first connection electrode CP1 to a sixth connection electrode CP6). The first connection electrode CP1 may be electrically connected to a first doped region of the active layer T10 of the first reset transistor T1 through the first pixel via hole V1, and may also be electrically connected to the first initial signal line INIT1 through the tenth pixel via hole V10. The second connection electrode CP2 may be electrically connected to a first doped region of the active layer of the second reset transistor in a previous row of pixel circuit through the eighth pixel via hole V8, and may also be electrically connected to the second initial signal line INIT2 through the eleventh pixel via V11. The third connection electrode CP3 may be electrically connected to the gate electrode T31 of the driving transistor T3 through the ninth pixel via hole V9, and may also be electrically connected to a first doped region of the active layer T20 of the threshold compensation transistor T2 through the second pixel via hole V2. The fourth connection electrode CP4 may be electrically connected to a second doped region of the active layer T60 of the second light emitting control transistor T6 through the fifth pixel via hole V5. The fifth connection electrode CP5 may be electrically connected to a first doped region of the active layer T70 of the second reset transistor T7 through the sixth pixel via hole V6, and may also be electrically connected to another second initial signal line INIT2 through the fifteenth pixel via hole V15. The sixth connection electrode CP6 may be electrically connected to a first doped region of the active layer of the first reset transistor of the next row of pixel circuit through the seventh pixel via hole V7, and may also be electrically connected to another first initial signal line INIT1 through the fourteenth via hole V14. The data line DL may be electrically connected to a first doped region of the active layer T40 of the data writing transistor T4 through the third pixel via hole V3. The first power line PL1 may be electrically connected to the shielding electrode BK through the twelfth pixel via hole V12, and may also be electrically connected to a first doped region of the active layer T50 of the first light emitting control transistor T5 through the fourth pixel via hole V4. The first power line PL1 may also be electrically connected to the second capacitor plate Cst-2 of the storage capacitor Cst through two thirteenth pixel via hole V13 arranged vertically.

The fabrication of the thin film transistor 84 in the pixel circuit is generally completed through the steps 2 to 6.

Step 7 includes: forming a planarization layer 83 and a pattern of a pixel definition layer 82 on the base substrate after step 6.

For example, a layer of an organic resin may be coated on the base substrate after step 6 to form the planarization layer, and the pixel definition layer material may be deposited on the planarization layer. A layer of photoresist is coated on the pixel definition layer material and is exposed using a mask to generate a photoresist unreserved region and a photoresist reserved region. The photoresist reserved region corresponds to a region where a pattern of the pixel definition layer material is located. The photoresist unreserved region corresponds to a region in addition to the region where the pattern of the pixel definition layer material is located. A developing process is performed, the photoresist in the photoresist unreserved region is completely removed and a thickness of the photoresist in the photoresist reserved region is maintained unchanged. The pixel definition layer material in the photoresist unreserved region is completely etched via an etching process, and remained photoresist is peeled off to form a pattern of the pixel definition layer. The pixel definition layer defines multiple pixel regions.

Step 8 includes: forming an anode 81 on the base substrate 212 after step 7.

For example, a transparent conductive layer having a thickness of about 300 to 1500Å is deposited on the base substrate after step 7 in a sputtering or thermal evaporation manner. The transparent conductive layer may be made of ITO, IZO or other transparent metallic oxides. A layer of photoresist is coated on the transparent conductive layer and is exposed using a mask to generate a photoresist unreserved region and a photoresist reserved region. The photoresist reserved region corresponds to a region where a pattern of an anode is located. The photoresist unreserved region corresponds to a region in addition to the region where the pattern of the anode is located. A developing process is performed, the photoresist in the photoresist unreserved region is completely removed, and a thickness of the photoresist in the photoresist reserved region is maintained unchanged. The transparent conductive layer in the photoresist unreserved region is completely etched via an etching process, and remained photoresist is peeled off to form the pattern of the anode.

Step 9 includes: forming a light-emitting layer and a cathode on the base substrate 212 after step 8.

For example, the light-emitting layer and the cathode are formed on the base substrate after step 8 in an evaporation manner.

The display substrate may be made through the above steps 1 to 9. In some embodiments, at regions corresponding to positions of the imaging holes, through holes can be provided in the layers above the imaging pattern, thereby increasing the light transmittance of the corresponding regions.

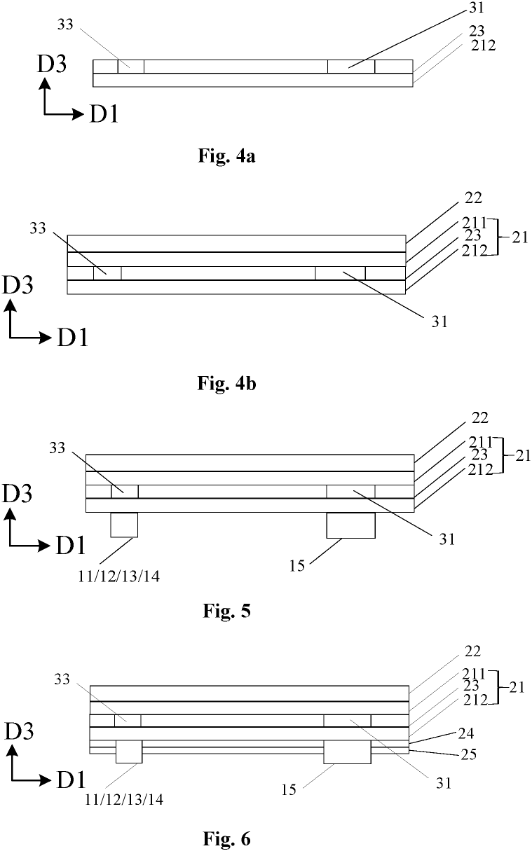

FIG. 3 is a schematic plan of a display device according to some embodiments of the present disclosure. As shown in FIG. 3, an effective display region 1 of the display device includes a first region A and a second region B. The first region A corresponds to a fingerprint recognition structure 15, and the second region B corresponds to a distance detection circuit 11, an environment light detection circuit 12, a face recognition circuit 13 and a camera 14 and so on. FIG. 4 is a schematic sectional view of the display device according to some embodiments of the present disclosure. As shown in FIG. 4, after a display substrate 21 and an encapsulation cover plate 22 are aligned and assembled, the fingerprint recognition structure 15 may be attached on a side of the display substrate 21 away from the encapsulation cover plate 22, and the fingerprint recognition structure 15 may be arranged directly facing the first region A; optical elements such as the distance detection circuit 11, the environment light detection circuit 12, the face recognition circuit 13 and the camera 14 may be attached on the side of the display substrate 21 away from the encapsulation cover plate 22, and may be arranged directly facing the second region B.

The first region A is provided with an imaging pattern 31. FIG. 2 is a schematic diagram of an imaging pattern according to some embodiments of the present disclosure. As shown in FIG. 2, the imaging pattern 31 includes multiple imaging holes 32. When a user touches the display substrate with a finger, a fingerprint may be imaged on a photoelectric converter in the fingerprint recognition structure 15 based on a pin-hole imaging principle.

A pixel density of an optical element arrangement region is set to be smaller than pixel densities of other display regions, such that a transmittance of the optical element arrangement region is higher than transmittances of the other display regions. The optical elements such as the face recognition circuit, the distance detection circuit and the environment light detection circuit may be arranged directly facing the second region. The optical elements may emit light and receive external light via the display substrate corresponding to the second region, to perform optical detections.

The distance detection circuit 11 may include an infrared emitting sensor and an infrared receiving sensor. The infrared emitting sensor emits infrared light via the display substrate corresponding to the second region B. The infrared light is reflected, after arriving at an obstacle, back to the infrared receiving sensor. The infrared receiving sensor may detect a distance based on the received infrared light.

The environment light detection circuit 12 may include a visible light detecting sensor. The environment light detection circuit 12 may accomplish an environment light detection based on a received visible light via the display substrate corresponding to the second region B.

The face recognition circuit 13 may include an infrared emitting sensor array and an infrared receiving sensor array. For example, the face recognition circuit 13 may include three thousand infrared emitting sensors arranged in an array and three thousand infrared receiving sensors arranged in an array. The infrared emitting sensors emit infrared lights via the display substrate corresponding to the second region B. The infrared lights are reflected, after arriving at an obstacle, back to the infrared receiving sensors. The infrared receiving sensors may accomplish recognition of a face of the user based on the received infrared lights.

In a case that a transmittance of the second region B is high enough, e.g., higher than 60%, the camera 14 may receive an external light via the second region B to accomplish photographing.

Since the infrared emitting sensor is arranged on the side of the display substrate 21 away from the encapsulation cover plate 22, in order to prevent a light emitted by the infrared emitting sensor from striking on the active layer of the thin film transistor and not affect the performance of the thin film transistor, it is necessary to arrange a light-shielding pattern to shield the active layer of the thin film transistor.

A display device is further provided according to some embodiments of the present disclosure. The display device includes the display substrate as provided by any of the embodiments. The display device further includes a sensor disposed at a side of the base substrate facing away from the plurality of first pixels. The sensor may be a fingerprint recognition structure or an under-screen camera.

The display device may be a television, a display, a digital camera, a cellphone, a tablet computer or any product or component having a displaying function. The display device may further include a flexible circuit board, a printed circuit board and a backboard.

For example, in a case that the thin film transistor is a low-temperature polysilicon thin film transistor and the active layer of the thin film transistor is made of a low-temperature polysilicon, the light-shielding layer may shield light emitted by a light source in the optical element, such that the light is prevented from striking onto the active layer made of the low-temperature polysilicon and the performance of the low-temperature polysilicon thin film transistor may not be affected. The light-shielding layer may be made of a metal such as Mo, or may be made of other light-shielding materials, which is not limited herein.

In some embodiments of the present disclosure, the optical element arrangement region may include a first region. The imaging pattern corresponds to the first region and is provided with multiple imaging holes arranged in an array. The optical element may include a fingerprint recognition structure. The fingerprint recognition structure may be arranged corresponding to the first region, for example, the fingerprint recognition structure is arranged directly facing the first region. A light source in the fingerprint recognition structure emits light out of the display substrate, and the light is reflected after arriving at a finger of a user. A photoelectric converter is arranged in the fingerprint recognition structure. Via the first region having a relatively high transmittance, the reflected light is received by the photoelectric converter based on a pin-hole imaging principle, a fingerprint of the user may be imaged on the photoelectric converter through the imaging holes, thereby accomplishing fingerprint acquisition at corresponding imaging holes. The photoelectric converter may utilize photosensitive components such as Complementary Metal Oxide Semiconductor (CMOS) or Charge-coupled Device (CCD), to acquire the fingerprint.

In some embodiments of the present disclosure, the display device further includes an optical element. An orthographic projection of the optical element onto the base substrate is at least partially located within the second area, and the optical element includes at least one of a face recognition circuit, a distance detection circuit, an environment light detection circuit and a camera. The optical element arrangement region may further include a second region. The light-shielding pattern corresponds to the second region and the other display regions. The optical element includes at least one of a face recognition circuit, a distance detection circuit and an environment light detection circuit. The at least one of the face recognition circuit, the distance detection circuit and the environment light detection circuit is arranged corresponding to the second region. The at least one of the face recognition circuit, the distance detection circuit and the environment light detection circuit may emit light or receive light via the second region of the display substrate, to perform an optical detection.

In some embodiments, the second region is close to the frame of the display device, and the display device is configured to display a low-resolution image in the second region, the low-resolution image includes at least one of images for battery level, signal strength, time and virtual button.

In some embodiments, in a case that the display device is a flexible display device, the base substrate is a flexible base substrate. In addition to the display substrate described above, the display device may further include a bottom film attached on the non-display side of the display substrate, and a buffering shielding layer located on a side of the bottom film away from the display substrate. An opening is provided in the bottom film, and the buffering shielding layer at a location corresponding to the optical element arrangement region and the optical element is arranged (e.g. directly) on the base substrate through the opening, such that the bottom film and the buffering shielding layer may not shield the external light, and the optical element is ensured to receive the external light.

FIG. 6 is a schematic cross-sectional view of a flexible display device according to some embodiments of the present disclosure taken along the line E1-E2 in FIG. 3. As shown in FIG. 6, in addition to the structure of the display device shown in FIG. 5, the flexible display device further includes a bottom film 24 and the buffer shielding layer 25 on the non-display side of the display substrate 21 (that is, the side facing away from the encapsulation cover plate 22). Openings is provided at the bottom film 24 and the buffer shielding layer 25 in positions corresponding first and second regions A and B. After a display substrate 21 and an encapsulation cover plate 22 are aligned and assembled, the fingerprint recognition structure 15 may be attached on a side of the display substrate 21 away from the encapsulation cover plate 22 through the opening corresponding to the first region A, and the fingerprint recognition structure 15 may be arranged directly facing the first region A; optical elements such as the distance detection circuit 11, the environment light detection circuit 12, the face recognition circuit 13 and the camera 14 may be attached on the side of the display substrate 21 away from the encapsulation cover plate 22 through the opening corresponding to the second region B, and may be arranged directly facing the second region B. Openings are provided in a bottom film 24 and a buffering shielding layer 25 at locations corresponding to the first region A and the second region B.

The first region A is provided with an imaging pattern 31. FIG. 2 is a schematic diagram of an imaging pattern according to some embodiments of the present disclosure. As shown in FIG. 2, the imaging pattern 31 includes multiple imaging holes 32. When a user touches the display substrate with a finger, a fingerprint may be imaged on a photoelectric converter in the fingerprint recognition structure 15 based on a pin-hole imaging principle.

A pixel density of the optical element arrangement region is set to be smaller than pixel densities of other display regions of the effective display region, such that a transmittance of the optical element arrangement region is higher than transmittances of the other display regions. The optical elements such as the face recognition circuit, the distance detection circuit and the environment light detection circuit may be arranged directly facing the second region. The optical elements can emit light and receive external light via the display substrate corresponding to the second region, to perform optical detections.

The distance detection circuit 11 may include an infrared emitting sensor and an infrared receiving sensor. The infrared emitting sensor emits an infrared light via the display substrate corresponding to the second region B. The infrared light is reflected, after arriving at an obstacle, back to the infrared receiving sensor. The infrared receiving sensor may detect a distance based on the received infrared light.

The environment light detection circuit 12 may include a visible light detecting sensor. The environment light detection circuit 12 may accomplish an environment light detection based on a received visible light via the display substrate corresponding to the second region B.

The face recognition circuit 13 may include an infrared emitting sensor array and an infrared receiving sensor array. For example, the face recognition circuit 13 may include 3000 infrared emitting sensors arranged in an array and 3000 infrared receiving sensors arranged in an array. The infrared emitting sensors emit infrared lights via the display substrate corresponding to the second region B. The infrared lights are reflected, after arriving at an obstacle, back to the infrared receiving sensors. The infrared receiving sensors may accomplish recognition of a face of the user based on the received infrared lights.

In a case that a transmittance of the second region B is high enough, e.g., higher than 60%, the camera 14 may receive an external light via the second region B to accomplish photographing.

Since the infrared emitting sensor is arranged on the side of the display substrate 21 away from the encapsulation cover plate 22, in order to prevent a light emitted by the infrared emitting sensor from striking on the active layer of the thin film transistor and not affect the performance of the thin film transistor, it is necessary to arrange a light-shielding pattern to shield the active layer of the thin film transistor. As shown in FIG. 1, an orthographic projection of the active layer 34 onto the base substrate may completely fall within an orthographic projection of the light-shielding pattern 33 onto the base substrate.

In some embodiments of the present disclosure, by setting transmittances of the light-shielding layer and the display device and by arranging the optical element at the non-display side of the display substrate, no reserved space at the bezel of the display device is necessary for arranging the optical element, the screen-to-body ratio of the display device is enhanced, and the display effect of the display device is optimized.

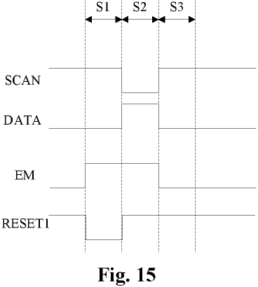

FIG. 14 is an equivalent circuit diagram for the pixel circuit according to at least one embodiment of the present disclosure. FIG. 15 is a timing diagram for the pixel circuit in FIG. 14. The pixel circuit of this exemplary embodiment may be any of the aforementioned first pixel circuit, second pixel circuit, or third pixel circuit. The pixel circuit of this exemplary embodiment is described by taking the 7T1C structure as an example, but the disclosure is not limited thereto.

In some exemplary implementations, as shown in FIG. 14, the pixel circuit in this example may include six switching transistors (T1, T2, and T4 to T7), one driving transistor T3 and one storage capacitor Cst. The six switching transistors are a data writing transistor T4, a threshold compensation transistor T2, a first light emitting control transistor T5, a second light emitting control transistor T6, a first reset transistor T1, and a second reset transistor T7. The light emitting element EL may include an anode, a cathode, and an organic light emitting layer disposed between the anode and the cathode.

In some example embodiments, the driving transistor and the six switching transistors may be P-type transistors, or may be N-type transistors. Using the same type of transistors in the pixel circuit can simplify the manufacturing process, reduce the difficulty of manufacturing the display substrate, and improve the yield of the product. In some possible implementations, the driving transistor and the six switching transistors may include P-type transistors and N-type transistors.

In some exemplary embodiments, the driving transistor and the six switching transistors may be low temperature polysilicon thin film transistors, or may be oxide thin film transistors, or may be low temperature polysilicon thin film transistors and oxide thin film transistors. The active layer of the low temperature polysilicon thin film transistor may include low temperature polysilicon (LTPS), and the active layer of the oxide thin film transistor may include oxide semiconductor (Oxide). Low temperature polysilicon thin film transistors have advantages such as high mobility and fast charging, and oxide thin film transistors have advantages such as low leakage current. The low temperature polysilicon thin film transistors and oxide thin film transistors are integrated on the display substrate to form a display substrate of low temperature polycrystalline oxide (LTPO), which can have the advantages of both types of transistors. In this way, a low-frequency driving, a reduction in power consumption, and an improved display quality can be realized.

In some exemplary embodiments, as shown in FIG. 14, the display substrate may include a scanning line GL, a data line DL, a first power line PL1, a second power line PL2, a light emitting control line EML, a first initial signal line INIT1, a second initial signal line INIT2, a first reset control line RST1 and a second reset control line RST2. In some examples, the first power line PL1 may be configured to provide a constant first voltage signal VDD to the pixel circuit, the second power line PL2 may be configured to provide a constant second voltage signal VSS to the pixel circuit, and the first voltage signal VDD is greater than the second voltage signal VSS. The scanning line GL may be configured to provide a scanning signal SCAN to the pixel circuit, the data line DL may be configured to provide a data signal DATA to the pixel circuit, the light emitting control line EML may be configured to provide a light emitting control signal EM to the pixel circuit, the first reset control line RST1 may be configured to provide a first reset control signal RESET1 to the pixel circuit, and the second reset control line RST2 may be configured to provide a second reset control signal RESET2 to the pixel circuit. In some examples, in the n-th row of pixel circuit, the first reset control line RST1 may be electrically connected to the scanning line GL of the (n-1)-th row of pixel circuit, so as to be inputted with the scanning signal SCAN(n-1), that is, the first The reset control signal RESET1(n) is the same as the scanning signal SCAN(n-1). The second reset control line RST2 may be electrically connected to the scanning line GL of the n-th row of pixel circuit, so as to be inputted with the scan signal SCAN(n), that is, the second reset control signal RESET2(n) is the same as the scan signal SCAN(n). In some examples, the second reset control line RST2 electrically connected to the n-th row of pixel circuit and the first reset control line RST1 electrically connected to the (n+1)-th row of pixel circuit may have an integral structure. n is an integer greater than 0. In this way, signal lines of the display substrate can be reduced, and a narrow frame design for the display substrate can be realized. However, the disclosure is not limited thereto.

In some exemplary embodiments, the first initial signal line INIT1 may be configured to provide a first initial signal to the pixel circuit, and the second initial signal line INIT2 may be configured to provide a second initial signal to the pixel circuit. For example, the first initial signal may be different from the second initial signal. The first initial signal and the second initial signal may be both constant voltage signals having magnitudes, for example, between the first voltage signal VDD and the second voltage signal VSS, but the disclosure is not limited thereto. In some other examples, the first initial signal and the second initial signal may be the same, and only the first initial signal line may be provided to provide the first initial signal.

In some exemplary embodiments, as shown in FIG. 14, the driving transistor T3 is electrically connected to the light emitting element EL, and the driving transistor T3 is controlled, by signals such as the scanning signal SCAN, the data signal DATA, the first voltage signal VDD, and the second voltage signal VSS, to output a driving current to drive the light emitting element EL to emit light. A gate electrode of the data writing transistor T4 is electrically connected to the scanning line GL, a first electrode of the data writing transistor T4 is electrically connected to the data line DL, and a second electrode of the data writing transistor T4 is electrically connected to a first electrode of the driving transistor T3. A gate electrode of the threshold compensation transistor T2 is electrically connected to the scanning line GL, a first electrode of the threshold compensation transistor T2 is electrically connected to a gate electrode of the driving transistor T3, and a second electrode of the threshold compensation transistor T2 is electrically connected to the second electrode of the driving transistor T3. A gate electrode of the first light emitting control transistor T5 is electrically connected to the light emitting control line EML, a first electrode of the first light emitting control transistor T5 is electrically connected to the first power line PL1, and a second electrode of the first light emitting control transistor T5 is connected to the first electrode of the driving transistor T3. A gate electrode of the second light emitting control transistor T6 is electrically connected to the light emitting control line EML, a first electrode of the second light emitting control transistor T6 is electrically connected to the second electrode of the driving transistor T3, and a second electrode of the second light emitting control transistor T6 is connected to an anode of the light emitting element EL. The first reset transistor T1 is electrically connected to the gate electrode of the driving transistor T3, and is configured to reset the gate electrode of the driving transistor T3. The second reset transistor T7 is electrically connected to the anode of the light emitting element EL, and is configured to reset the anode of the light emitting element EL. A gate electrode of the first reset transistor T1 is electrically connected to the first reset control line RST1, a first electrode of the first reset transistor T1 is electrically connected to the first initial signal line INIT1, and a second electrode of the first reset transistor T1 is electrically connected to the gate electrode of the driving transistor T3. A gate electrode of the second reset transistor T7 is electrically connected to the second reset control line RST2, a first electrode of the second reset transistor T7 is electrically connected to the second initial signal line INIT2, and a second electrode of the second reset transistor T7 is connected to the anode of the light emitting element EL. A first capacitor plate of the storage capacitor Cst is electrically connected to the gate electrode of the driving transistor T3, and a second capacitor plate of the storage capacitor Cst is electrically connected to the first power line PL1.

In this example, a first node N1 is a point for connecting the storage capacitor Cst, the first reset transistor T1, the driving transistor T3 and the threshold compensation transistor T2. A second node N2 is a point for connecting the first light emitting control transistor T5, the data writing transistor T4 and the driving transistor T3. A third node N3 is a point for connecting the driving transistor T3, the threshold compensation transistor T2 and the second light emitting control transistor T6, and a fourth node N4 is a point for connecting the second light emitting control transistor T6, the second reset transistor T7 and the light emitting element EL.

The operation of the pixel circuit shown in FIG. 14 will be described below with reference to FIG. 15. An example, in which transistors in the pixel circuit shown in FIG. 14 are all P-type transistors, is taken for illustration.

In some exemplary implementations, as shown in FIG. 15, during one frame of display period, the operation process of the pixel circuit may include: a first stage S1, a second stage S2 and a third stage S3.

The first stage S1 is called a reset stage. The first reset control signal RESET 1 provided by the first reset control line RST1 is a low-level signal to switch on the first reset transistor T1, and the first initial signal provided by the first initial signal line INIT1 is provided to the first node N1. The first node N1 is initialized to clear original data voltage in the storage capacitor Cst. The scanning signal SCAN provided by the scanning line GL is a high-level signal, and the light emitting control signal EM provided by the light-emitting control line EML is a high-level signal, so that the data writing transistor T4, the threshold compensation transistor T2, the first light-emitting control transistor T5, the second light emitting control transistor T6 and the second reset transistor T7 are switched off. At this stage, the light emitting element EL does not emit light.

The second stage S2 is called a data writing stage or a threshold compensation stage. The scanning signal SCAN provided by the scanning line GL is a low level signal, the first reset control signal RESET 1 provided by the first reset control line RST1 and the light emitting control signal EM provided by the light emitting control line EML are both high level signals, and the data line DL outputs the data signal DATA. At this stage, since the first capacitor plate of the storage capacitor Cst is at a low level, the driving transistor T3 is switched on. The scanning signal SCAN is a low level signal, which enables the threshold compensation transistor T2, the data writing transistor T4 and the second reset transistor T7 to be switched on. The threshold compensation transistor T2 and the data writing transistor T4 are switched on, so that the data voltage Vdata outputted by the data line DL is provided to the first node N1 via the second node N2, the switched-on driving transistor T3, the third node N3, and the switched-on threshold compensation transistor T2, and the storage capacitor Cst is charged with a difference between the data voltage Vdata outputted by the data line DL and the threshold voltage of the driving transistor T3. The voltage of the first capacitor plate of the storage capacitor Cst (that is, the first node N1) is Vdata- |Vth|, wherein, Vdata is the data voltage output by the data line DL, and Vth is the threshold voltage of the driving transistor T3. The second reset transistor T7 is switched on, so that the second initial signal provided by the second initial signal line INIT2 is supplied to the anode of the light-emitting element EL, and the anode of the light-emitting element EL is initialized (reset) to clear a pre-stored voltage inside the light-emitting element EL as the initialization, thereby ensuring that the light-emitting element EL does not emit light. The first reset control signal RESET 1 provided by the first reset control line RST1 is a high level signal to switch off the first reset transistor T1. The light emitting control signal EM provided by the light emitting control signal line EML is a high level signal, which enables the first light emitting control transistor T5 and the second light emitting control transistor T6 to be switched off.

The third stage S3 is called the light-emitting stage. The emitting control signal EM provided by the emitting control signal line EML is a low-level signal, and the scanning signal SCAN provided by the scanning line GL and the first reset control signal RESET1 provided by the first reset control line RST1 are high-level signals. The light emitting control signal EM provided by the light emitting control signal line EML is a low-level signal, so that the first light emitting control transistor T5 and the second light emitting control transistor T6 are switched on, and the first voltage signal VDD outputted by the first power line PL1 is supplied, as the driving voltage, to the anode of the light emitting element EL via the switched-on first light emitting control transistor T5, the driving transistor T3 and the second light emitting control transistor T6, so as to drive the light emitting element EL to emit light.

During the driving process of the pixel circuit, the driving current flowing through the driving transistor T3 is determined by the voltage difference between the gate electrode and the first electrode thereof. Since the voltage of the first node N1 is Vdata-|Vth|, the driving current of the driving transistor T3 is:

$$\begin{matrix}\text{I=K} \times {\left(\text{Vgs-Vth}\right)}^{2} \text{=K} \times {\left[\left(\text{VDD-Vdata+} \left|\text{Vth}\right|\right) \text{-Vth}\right]}^{2} \text{=} \\ \text{K} \times {\left[\text{VDD-Vdata}\right]}^{2}\end{matrix}$$

Wherein, I is the driving current flowing through the driving transistor T3, that is, the driving current for driving the light-emitting element EL, K is a constant, Vgs is the voltage difference between the gate electrode and the first electrode of the driving transistor T3, and Vth is the driving current of the driving transistor T3. Vdata is the data voltage outputted from the data line DL, and VDD is the first voltage signal outputted from the first power line PL1.

It can be seen from the above formula that the current flowing through the light emitting element EL does not relate to the threshold voltage of the driving transistor T3. Therefore, the pixel circuit of this embodiment can better compensate the threshold voltage of the driving transistor T3.

In the embodiments of the present disclosure, numbering of the steps does not necessarily define a sequence of the steps. Variation of the sequence of the steps also falls into the protection scope of the present disclosure for one of ordinary skills in the art on the premise of paying not creative work.

Unless otherwise defined, technical terms or scientific terms used in the present disclosure should be interpreted according to common meanings thereof as commonly understood by those of ordinary skills in the art. Such terms as “first”, “second” and the like used in the present disclosure do not represent any order, quantity or importance, but are merely used to distinguish different components. Such terms as “including”, or “comprising” and the like mean that an element or an article preceding the term contains elements or items and equivalents thereof behind the term, but does not exclude other elements or items. Such terms as “connected”, or “interconnected” and the like are not limited to physical or mechanical connections, but may include electrical connections, whether direct connection or indirect connection. Such terms as “on”, “under”, “left”, “right” and the like are only used to represent a relative position relationship, and when an absolute position of a described object is changed, the relative position relationship thereof may also be changed accordingly.

It may be understood that when an element such as a layer, a film, a region or a substrate is referred to as being “on” or “under” another element, the element may be “directly” “on” or “under” the another element, or there may exist an intervening element.

The above embodiments are merely optional embodiments of the present disclosure. It should be noted that numerous improvements and modifications may be made by those skilled in the art without departing from the principle of the present disclosure, and these improvements and modifications shall also fall within the scope of the present disclosure.

What is claimed is:

1. A display substrate, wherein the display substrate comprises an effective display region, the effective display region comprises a first region and other display regions located on at least one side of the first region, a transmittance of the first region is greater than transmittances of the other display regions, and the display substrate comprises:
a base substrate;
a plurality of first pixels in the first region, located at a side of the base substrate, wherein at least one of the plurality of first pixels comprises a first pixel circuit and a first light emitting element, the first pixel circuit is configured to drive the first light-emitting element to emit light, and the first pixel circuit comprises a thin film transistor; and
a light-shielding layer, located between the base substrate and the first pixel circuit, the light-shielding layer comprises a shielding portion located in the first region, and an orthographic projection of the first pixel circuit onto the base substrate is located within an orthographic projection of the shielding portion onto the base substrate.

2. The display substrate according to claim 1, wherein the display substrate further comprises:
a plurality of second pixels in the other display regions, located at the side of the base substrate, wherein at least one of the plurality of second pixels comprises a second pixel circuit and a second light emitting element, the second pixel circuit is configured to drive the second light emitting element to emit light, and the second pixel circuit comprises a thin film transistor; and
wherein the light-shielding layer further comprises a first light-shielding pattern in the other display regions, and an orthographic projection of the second pixel circuit onto the base substrate is located within an orthographic projection of the first light-shielding pattern onto the base substrate.

3. The display substrate according to claim 2, wherein a size of the orthographic projection of the first pixel circuit in the first region onto the base substrate is smaller than a size of the orthographic projection of the second pixel circuit in the other display regions onto the base substrate.

4. The display substrate according to claim 2, wherein a distance between two adj acent first pixel circuits in the first region is greater than a distance between two adj acent second pixel circuits in the other display regions.

5. The display substrate according to claim 1, wherein a pixel density for the plurality of first pixels in the first region is lower than 200 pixels per inch.

6. The display substrate according to claim 1, further comprising:
a plurality of imaging holes arranged in an array, the plurality of imaging holes are arranged in the shielding portion of the light-shielding layer, and the plurality of imaging holes is configured to enable the light to transmitted therethrough.

7. The display substrate according to claim 2, wherein the effective display region of the display substrate further comprises a second region, a transmittance of the second region is greater than the transmittances of the other display regions, the display substrate further comprises:
a plurality of third pixels in the second region, located at the side of the base substrate, at least one of the plurality of third pixels comprises a third pixel circuit and a third light emitting element, the third pixel circuit is configured to drive the third light emitting element to emit light, and the third pixel circuit comprises a thin film transistor; and
wherein the light-shielding layer further comprises a second light-shielding pattern in the second region, and an orthographic projection of the third pixel circuit onto the base substrate is located within an orthographic projection of the second light-shielding pattern onto the base substrate.

8. The display substrate according to claim 7, wherein a size of the orthographic projection of the third pixel circuit in the second region onto the base substrate is smaller than a size of the orthographic projection of the second pixel circuit in the other display regions onto the base substrate.

9. The display substrate according to claim 7, wherein the shielding portion, the first shielding pattern and the second shielding pattern are located in the same layer and comprise the same material.

10. The display substrate according to claim 7, wherein the first light-shielding pattern, the second light-shielding pattern, and respective active layers have substantially the same size and shape, wherein the respective active layers are active layers of thin film transistors corresponding to the first light-shielding pattern and the second light-shielding pattern, respectively.

11. The display substrate according to claim 7, wherein the second region comprises a first sub-region and a second sub-region, and a light-shielding portion of the second light-shielding pattern located in at least one of the first sub-region and the second sub-region is capable of blocking infrared light, and the first sub-region and the second sub-region are arranged to be opposite to a face recognition circuit and a distance detection circuit, respectively.

12. The display substrate according to claim 7, wherein the second light-shielding pattern comprises at least two light-shielding portions, and in the second region, active layers of at least two thin film transistors are arranged on a light-shielding portion in the second light-shielding pattern, and an active layer of at least one thin film transistor adjacent to the at least two thin film transistors is arranged on another light-shielding portion in the second light-shielding pattern.

13. The display substrate according to claim 1, wherein the thin film transistor has a top-gate structure, and an orthographic projection of an active layer of the thin film transistor onto the base substrate falls within an orthographic projection of a gate electrode of the thin film transistor onto the base substrate.

14. A display device, comprising a display substrate, wherein the display substrate comprises an effective display region, the effective display region comprises a first region and other display regions located on at least one side of the first region, a transmittance of the first region is greater than transmittances of the other display regions, and the display substrate comprises:
a base substrate;
a plurality of first pixels in the first region, located at a side of the base substrate, wherein at least one of the plurality of first pixels comprises a first pixel circuit and a first light emitting element, the first pixel circuit is configured to drive the first light-emitting element to emit light, and the first pixel circuit comprises a thin film transistor; and
a light-shielding layer, located between the base substrate and the first pixel circuit, the light-shielding layer comprises a shielding portion located in the first region, and an orthographic projection of the first pixel circuit onto the base substrate is located within an orthographic projection of the shielding portion onto the base substrate; and
wherein the display device further comprises:
a sensor, arranged at another side of the base substrate facing away from the plurality of first pixels.

15. The display device according to claim 14, wherein the display substrate further comprises:
a plurality of second pixels in the other display region, located at the side of the base substrate, wherein at least one of the plurality of second pixels comprises a second pixel circuit and a second light emitting element, The second pixel circuit is configured to drive the second light emitting element to emit light, and the second pixel circuit comprises a thin film transistor; and
wherein the light-shielding layer further comprises a first light-shielding pattern in the other display regions, and an orthographic projection of the second pixel circuit onto the base substrate is located within an orthographic projection of the first light-shielding pattern onto the base substrate.

16. The display device according to claim 15, wherein a size of the orthographic projection of the first pixel circuit in the first region onto the base substrate is smaller than a size of the orthographic projection of the second pixel circuit in the other display regions onto the base substrate; or
a distance between two adjacent first pixel circuits in the first region is greater than a distance between two adjacent second pixel circuits in the other display regions.

17. The display device according to claim 14, wherein the effective display region comprises a second region, the second region is adjacent to a frame of the display device, and a transmittance of the second region is greater than the transmittance of the other display regions, and the sensor comprises:
a camera, wherein an orthographic projection of the camera onto the base substrate is at least partially located within the first region; and
an optical element, wherein an orthographic projection of the optical element onto the base substrate is at least partially located within the second region, and the optical element comprises at least one of a face recognition circuit, a distance detection circuit, an environment light detection circuit, and a camera.

18. The display device according to claim 15, wherein the display device is configured to display an image with a low resolution in the second region, and the image comprises at least one of an image for battery level, an image for signal strength, an image for time or an image for virtual button.

19. The display device according to claim 14, wherein the display device is a flexible display device, and the display device further comprises a bottom film attached onto a non-display side of the display substrate, and a buffering shielding layer located on a side of the bottom film away from the display substrate, an opening is provided in the bottom film and the buffering shielding layer at a location corresponding to the optical element arrangement region, and the sensor is arranged on the base substrate through the opening.

20. A method for manufacturing a display substrate, the display substrate comprising an effective display region, the effective display region comprising a first region and other display regions located on at least one side of the first region, a transmittance of the first region being greater than transmittances of the other display regions, wherein the method comprises:
forming the base substrate;
forming a light-shielding layer on the base substrate, comprising: forming a shielding portion located in the first region;
forming a thin film transistor array on the light-shielding layer, the thin film transistor array comprising a plurality of first pixels in the first region, at least one of the plurality of first pixels comprising a first pixel circuit and a first light emitting element, the first pixel circuit being configured to drive the first light-emitting element to emit light, the first pixel circuit comprising a thin film transistor, and an orthographic projection of the first pixel circuit onto the base substrate being located within an orthographic projection of the shielding portion onto the base substrate; and
forming an anode, a light-emitting layer, and a cathode on the thin film transistor array.
